(19) United States
(12) Patent Application Publication
(10) Pub. No.: US 2025/0079807 A1
(43) Pub. Date: Mar. 6, 2025

(54) SEMICONDUCTOR OPTICAL AMPLIFIER

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HITOSHI YAMADA, Nisshin-shi (JP); KOICHI OYAMA, Nisshin-shi (JP)

(21) Appl. No.: 18/748,384

(22) Filed: Jun. 20, 2024

(30) Foreign Application Priority Data
Sep. 6, 2023 (JP) 2023-144695

(51) Int. Cl. H01S 5/50; H01S 5/026; H01S 5/343

(52) U.S. Cl. CPC H01S 5/50; H01S 5/026; H01S 5/343

(57) ABSTRACT

A semiconductor optical amplifier includes: a waveguide layer through which a light propagates; and active layers having higher average refractive index than the waveguide layer to amplify a light. The active layers include a first active layer stacked on an upper surface of the waveguide layer and a second active layer stacked on a lower surface of the waveguide layer.

### CROSS REFERENCE TO RELATED APPLICATION

This application is based on Japanese Patent Application No. 2023-144695 filed on Sep. 6, 2023, the disclosure of which is incorporated herein by reference.

### TECHNICAL FIELD

The present disclosure relates to a semiconductor optical amplifier (SOA).

### BACKGROUND

In an optical transceiver device such as a light detection and ranging (LiDAR) equipped with photonic ICs (integrated circuits) for transmitting and receiving optical signals, a semiconductor optical amplifier (SOA) is placed after a laser light source that generates a certain signal light. The output light of the laser light source is amplified to secure the necessary light output.

### SUMMARY

According to one aspect of the present disclosure, a semiconductor optical amplifier includes a waveguide layer through which light propagates, and active layers having higher average refractive index than the waveguide layer to amplify the light. The active layers are stacked at least on the upper surface and the lower surface of the waveguide layer.

### BRIEF DESCRIPTION OF DRAWINGS

FIG. 1 is a cross-sectional view of a semiconductor optical amplifier according to a first embodiment.

FIG. 2 is a cross-sectional view of a first comparative example.

FIG. 3 is a cross-sectional view of a second comparative example.

FIG. 4 is a diagram showing a relationship between an output power and a gain (amplification factor) of the semiconductor optical amplifier.

FIG. 5 is a diagram showing a saturation output power of the semiconductor optical amplifier.

FIG. 6 is a cross-sectional view of a semiconductor optical amplifier according to a second embodiment.

FIG. 7 is a cross-sectional view of a semiconductor optical amplifier according to a third embodiment.

FIG. 8 is a cross-sectional view of a semiconductor optical amplifier according to a fourth embodiment.

### DETAILED DESCRIPTION

In an optical transceiver device such as LiDAR equipped with photonic ICs (integrated circuits) for transmitting and receiving optical signals, a semiconductor optical amplifier (SOA) is placed after a laser light source that generates a certain type of signal light, and the output light of the laser light source is amplified, so as to secure the necessary light output.

An optical transceiver device is mounted on a vehicle for use in advanced driving support systems, automatic driving systems, and the like. In this case, considering the environmental temperature and sensing requirements in a free space to achieve the above applications, high optical output is required to the SOA in a wide temperature range, typically from −40° C. to 85° C. or more, in the wide wavelength band compared to optical transmitter/receivers for communications. Furthermore, in consideration of various in-vehicle requirements, it is desirable to operate the SOA at the desired performance without installing a thermoelectric cooler (TEC), or to enhance the SOA performance while reducing the operating power even if the TEC is used. However, in the SOAs designed for communications, even if strict temperature control is performed using the TEC, the output typically saturates before such high output is achieved.

In order to improve the output saturation limit and obtain high output, for example, in the SOA, two active layers of different materials and thicknesses are arranged on the input side and the output side of the optical signal, and the two active layers are connected by the butt joint to improve the light output.

However, the manufacturing cost of the SOA is increased, due to a complicated configuration, in which the two active layers of different materials and thicknesses are arranged in the same layer.

The present disclosure provides an SOA to obtain high output with a simple configuration.

According to one aspect of the present disclosure, a semiconductor optical amplifier includes a waveguide layer through which light propagates, and active layers having higher average refractive index than the waveguide layer to amplify the light. The active layers are stacked at least on the upper surface and the lower surface of the waveguide layer.

In this way, by stacking the active layers on the top and bottom sides of the waveguide layer, it is possible to obtain high output even with a simple configuration in which the active layers have the same configuration from the input end to the output end.

Hereinafter, embodiments of the present disclosure will be described with reference to the drawings. In each embodiment described below, same or equivalent parts are designated with the same reference numerals.

### First Embodiment

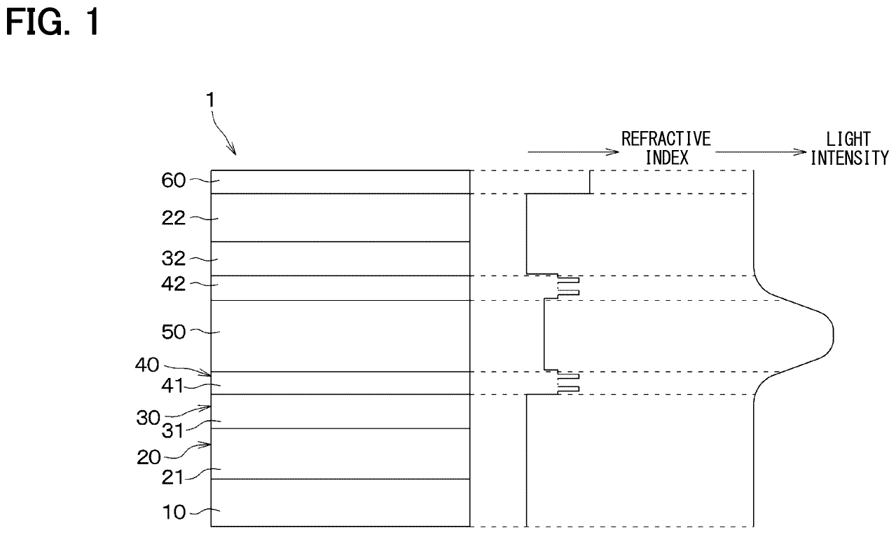

A first embodiment is described. A semiconductor optical amplifier (SOA) 1 of this embodiment shown in FIG. 1 is used, for example, in an optical transmitting device such as LiDAR. In this embodiment, the SOA 1 is used as an optical transmitting device, but the SOA 1 may be used for other purposes. The optical transmitting device includes the SOA 1, a laser light source, a transmitting section, a receiving section, a light receiving section, and a signal processing section. The SOA 1, the laser light source, the transmitting section, the receiving section, and the light receiving section are formed in a photonic IC.

The SOA 1 amplifies input light and outputs the amplified light. The SOA 1 may be B-SOA (Booster-SOA). Details of the SOA 1 will be described later. The SOA 1 is arranged after the laser light source and is connected to the laser light source by a waveguide on the photonic IC. Further, the SOA 1 is connected to the transmitting section by a waveguide on the photonic IC.

The laser light source outputs a kind of signal light. The output light of the laser light source is amplified by the SOA 1 and then input to the transmitting section.

The transmitting section transmits an optical signal for distance measurement to the outside. The receiving section receives an optical signal incident from the outside. The optical signal transmitted by the transmitting section is reflected by an external object and received by the receiving section. The optical signal received by the receiving section is input to the light receiving section.

The light receiving section is composed of a photodetector and the like. The light receiving section is connected to the signal processing section by electrical wiring, and the output signal of the light receiving section is input to the signal processing section.

The signal processing section calculates the position of the object that reflected the transmitted signal based on the output signal of the light receiving section.

The details of the SOA 1 will be explained. As shown in FIG. 1, the SOA 1 includes a substrate 10, a cladding layer 20, a spacer layer 30, an active layer 40, a waveguide layer 50, and a contact layer 60.

The substrate 10 is made of, for example, n type InP (indium phosphide). An electrode (not shown) for applying a voltage to the SOA 1 is formed on the lower surface of the substrate 10. The cladding layer 20 is formed on the upper surface of the substrate 10.

The cladding layer 20 is configured to confine the input light from the laser light source in the active layer 40 and the waveguide layer 50, and is formed on the upper surface and the lower surface of a stacked structure of the active layer 40 and the waveguide layer 50. Specifically, the cladding layer 20 includes a cladding layer 21 stacked on the upper surface of the substrate 10 and a cladding layer 22 stacked on an upper surface of a spacer layer 32, which will be described later. The cladding layer 21 is made of, for example, n+ type InP, and the cladding layer 22 is made of, for example, p+ type InP.

The spacer layer 30 is formed between the cladding layer 20 and the active layer 40 to adjust the distance between the cladding layer 20 and the active layer 40, and is formed between the cladding layer 20 and the waveguide layer 50 to adjust the distance between the cladding layer 20 and the waveguide layer 50. Specifically, the spacer layer 30 includes a spacer layer 31 formed between the cladding layer 21 and the active layer 41, and a spacer layer 32 formed between the cladding layer 22 and the active layer 42. The spacer layer 31 is made of, for example, n′ type InP, and the spacer layer 32 is made of, for example, p⁻ type InP. Further, the spacer layer 31 may be made of, for example, n⁻ type InGaAsP (indium gallium arsenide phosphide), and the spacer layer 32 may be made of, for example, p⁻ type InGaAsP. The thickness of the spacer layer 31 and the thickness of the spacer layer 32 may be the same, or may have a size relationship as appropriate.

The active layer 40 amplifies the light incident on the SOA 1, and is formed on the upper surface and the lower surface of the waveguide layer 50. Specifically, the active layer 40 includes an active layer 41 formed between the spacer layer 31 and the waveguide layer 50, and an active layer 42 formed between the spacer layer 32 and the waveguide layer 50.

The active layer 40 includes, for example, a bulk structure, a single quantum well (SQW) structure, and a multiple quantum well (MQW) structure. The active layer 40 includes, for example, a single quantum dot (SQD) structure and a multiple quantum dot (MQD) structure. The active layer 40 may be configured to include only one of a bulk structure, an SQW structure, an MQW structure, an SQD structure, and an MQD structure, or may include some of a bulk structure, an SQW structure, an MQW structure, an SQD structure, and an MQD structure.

The MQW structure has, for example, a structure in which quantum well layers made of InGaAsP and barrier layers made of n-type InP are alternately stacked. The MQD structure has, for example, a structure in which quantum dot layers made of InAs (indium arsenide) and barrier layers made of GaAs (gallium arsenide) are alternately stacked.

The active layer 41, 42 has the same configuration from the input end to the output end. For example, the active layer 41, 42 is made of the same material from the input end to the output end, and has the same thickness from the input end to the output end. Furthermore, in this embodiment, the active layers 41 and 42 have the same configuration. For example, each of the active layers 41 and 42 is composed of three layers of MQW.

The waveguide layer 50 propagates a light incident on the SOA 1. The waveguide layer 50 is made of, for example, undoped InGaAsP, specifically, undoped or unintentionally doped (UID) InGaAsP. The waveguide layer 50 has a higher refractive index than the cladding layer 20. Further, the waveguide layer 50 may have a refractive index higher than that of the spacer layer 30, or may have a refractive index equivalent to that of the spacer layer 30. For example, when the spacer layer 31, 32 is made of InGaAsP, the spacer layer 31, 32 may have the same refractive index as the waveguide layer 50. In this case, the spacer layer 31, 32 not only adjusts the distance between the cladding layer 21, 22 and the active layer 41, 42 and the waveguide layer 50, but also functions propagating some of the light incident on the SOA 1 to the spacer layer 31, 32. Furthermore, by making the film thicknesses of the spacer layers 31 and 32 different from each other, the refractive index distribution in the stacked structure of the spacer layer 30, the active layer 40, and the waveguide layer 50 can be adjusted asymmetrical relative to the central plane of the waveguide layer 50. This central plane is a plane that passes through the center of the waveguide layer 50 in the thickness direction, that is, in the stacking direction, and is perpendicular to this thickness direction. The active layer 40 has a higher average refractive index than the waveguide layer 50.

The contact layer 60 is made of p⁺⁺ type InGaAs, for example. An electrode (not shown) for applying a voltage to the SOA 1 is formed on the upper surface of the contact layer 60. By applying a voltage to the SOA 1 through the electrodes formed on the lower surface of the substrate 10 and the upper surface of the contact layer 60, light propagating through the waveguide layer 50 is amplified by the active layer 40.

In this way, in the SOA 1 of this embodiment, the cladding layer 21, the spacer layer 31, the active layer 41, the waveguide layer 50, the active layer 42, the spacer layer 32, the cladding layer 22, and the contact layer 60 are arranged in this order on the substrate 10.

In the SOA, carriers are consumed as light propagates, and the output becomes saturated. The saturated output can be improved by distributing the light intensity in a low-loss waveguide region to reduce the optical confinement coefficient. The thickness of the waveguide influences the optical confinement coefficient.

In a structure in which an active layer is laminated on one side of a waveguide layer, the light intensity is distributed to the active layer whose refractive index is higher than that of the waveguide layer. However, for example, by making the waveguide layer extremely thick, the light intensity is distributed into the waveguide layer to reduce the optical confinement coefficient. An improvement in the saturated output can be expected if the thickness of the waveguide region composed of the active layer and the waveguide layer can be kept relatively thin while distributing the light intensity in the low-loss waveguide layer. However, when the waveguide layer is made thicker, the power conversion efficiency decreases due to an increase in series resistance.

In contrast, in this embodiment, the active layers 41 and 42 having a higher refractive index than the waveguide layer 50 are arranged on the upper surface and the lower surface of the waveguide layer 50. In such a configuration, even when the waveguide layer 50 is thin, a region with high light intensity is distributed near the center of the waveguide layer 50 by adjusting the balance of refractive index in the cross section of the path through which light propagates. It is possible to improve the saturation output power by reducing the optical confinement coefficient.

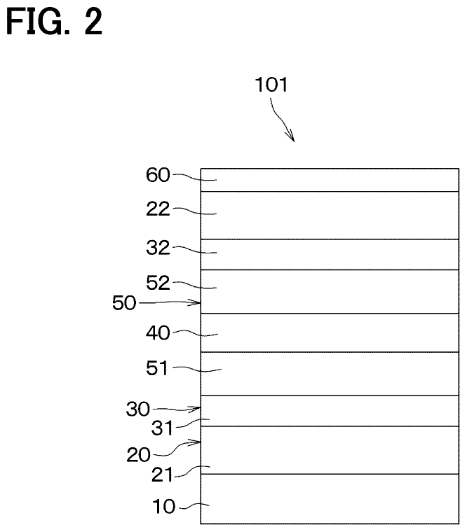

A first comparative example is described. In an SOA 101 of Comparative Example 1 shown in FIG. 2, a waveguide layer 50 includes a waveguide layer 51 arranged on the lower surface of the active layer 40 and a waveguide layer 52 arranged on the upper surface of the active layer 40. That is, the SOA 101 has a structure in which a cladding layer 21, a spacer layer 31, a waveguide layer 51, an active layer 40, a waveguide layer 52, a spacer layer 32, a cladding layer 22, and a contact layer 60 are laminated in this order on a substrate 10.

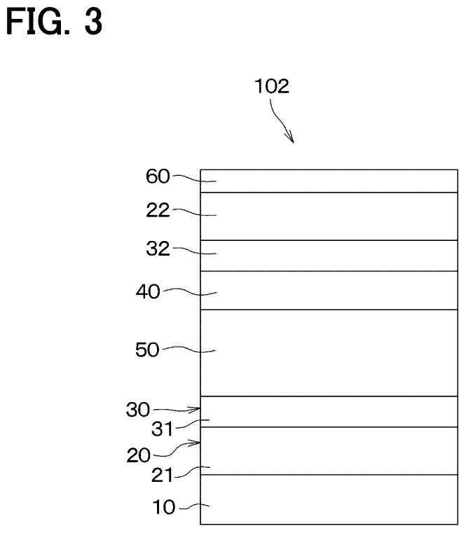

A second comparative example is described. In an SOA 102 of Comparative Example 2 shown in FIG. 3, the active layer 40 is disposed on the upper surface of the waveguide layer 50. That is, the SOA 102 has a structure in which a cladding layer 21, a spacer layer 31, a waveguide layer 50, an active layer 40, a spacer layer 32, a cladding layer 22, and a contact layer 60 are laminated in this order on a substrate 10.

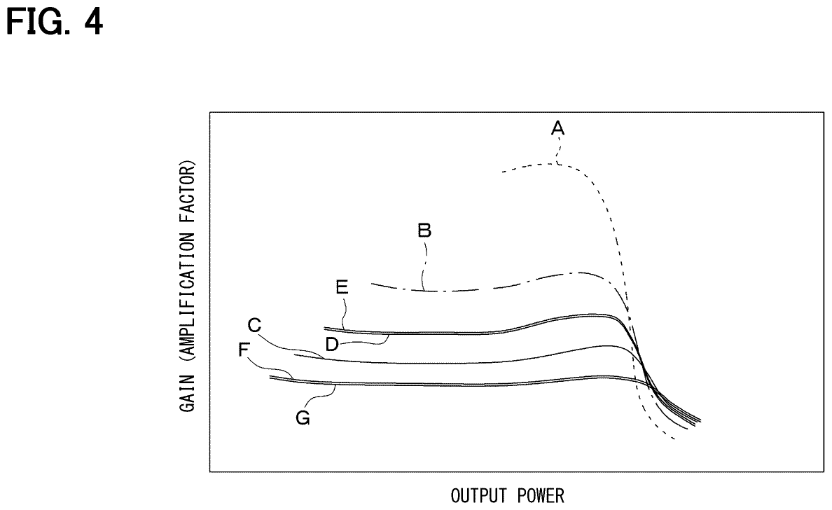

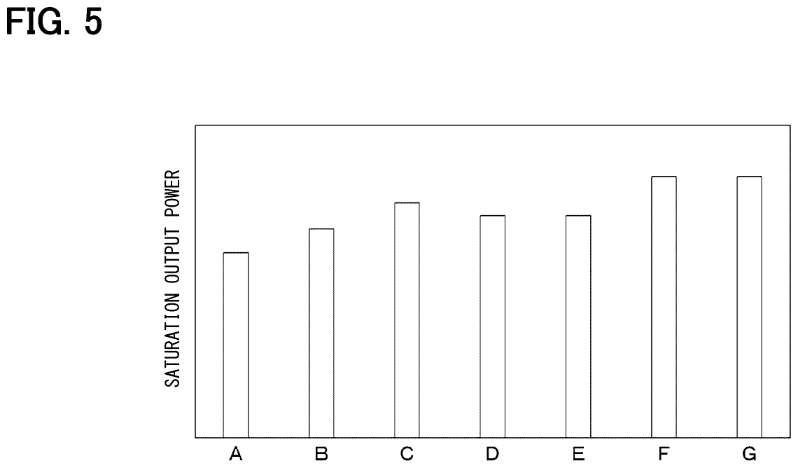

FIGS. 4 and 5 show results of simulations conducted for Comparative Examples 1 and 2, this embodiment, and second to fourth embodiments to be described later. In this embodiment, the simulation was performed with the spacer layer 31 made of n⁻ type InP and the spacer layer 32 made of p⁻ type InP. In FIGS. 4 and 5, Data A and B are the simulation results of Comparative Examples 1 and 2, respectively, and data C and D are the simulation results of the present embodiment. In the data of A, the thickness of the waveguide layer 51, 52 is 0.3 μm. In the data of B, the thickness of the waveguide layer 50 is 0.6 μm. In the data of C, the thickness of the waveguide layer 50 is 0.6 μm. In the data of D, the thickness of the waveguide layer 50 is 0.9 μm. Further, in the data A and B, the active layer 40 has a configuration including six layers of MQW. Furthermore, in the data C and D, each of the active layers 41 and 42 includes three layers of MQW.

As shown in FIG. 4, in the SOA 1 of this embodiment, the amplification factor in the large output region, that is, the gain is larger than that in the SOA 101, 102. Further, as shown in FIG. 5, the saturation output power of the SOA 1 of this embodiment is larger than that of the SOA 101, 102.

As explained above, in this embodiment, the active layer 40 having a higher refractive index than the waveguide layer 50 is laminated on the upper surface and the lower surface of the waveguide layer 50. According to this, even in a simple configuration in which the active layer 40 has the same configuration from the input end to the output end, the saturation output power can be improved and high output can be obtained by reducing the optical confinement coefficient.

Furthermore, in order to obtain optical coupling with the subsequent stage, the intensity distribution of the output light of the SOA is required to allow easy propagation to the subsequent waveguide. In this embodiment, the mode of the guided light is the same as that in Comparative Examples 1 and 2, so that it is possible to suppress a decrease in the coupling efficiency with the waveguide.

Furthermore, in the SOA 1 of this embodiment, the high output can be obtained even if the thickness of the waveguide layer 50 is the same as that of Comparative Example 1, 2. Therefore, it is possible to suppress an increase in series resistance due to an increase in the thickness of the waveguide layer 50, and to suppress a decrease in power conversion efficiency. As a result, heat generation can be reduced, so that deterioration in performance within the in-vehicle temperature range due to heat generation of the SOA 1 itself can be suppressed. Moreover, even when using the TEC, its operating power can be reduced. In this way, the SOA 1 of this embodiment is suitable as an in-vehicle SOA.

### Second Embodiment

A second embodiment will be described. This embodiment differs from the first embodiment in that the configuration of the stacked structure of the active layer 40 and the waveguide layer 50, and other aspects are the same as in the first embodiment. Only the different parts will be explained.

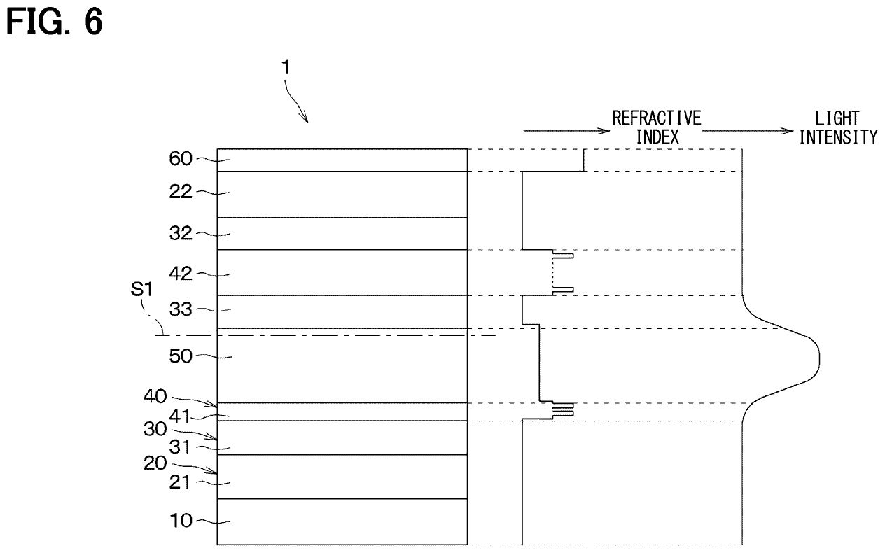

As shown in FIG. 6, in this embodiment, the stacked structure of the active layer 40 and the waveguide layer 50 is asymmetrical with respect to the central plane S1 in the thickness direction. That is, the stacked structure of the active layer 40 and the waveguide layer 50 has different configurations between the upper portion and the lower portion of the central plane S1. The central plane S1 is a plane perpendicular to the thickness direction and passing through the center of the stacked structure of the active layer 40 and the waveguide layer 50 in the thickness direction, that is, the stacking direction.

Specifically, the spacer layer 30 includes a spacer layer 33 in addition to the spacer layers 31 and 32, and the spacer layer 33 is stacked between the waveguide layer 50 and the active layer 42. As a result, the optical distance to the center of the waveguide layer 50 in the thickness direction is different between the active layer 42 stacked above the upper surface of the waveguide layer 50 and the active layer 41 stacked below the lower surface of the waveguide layer 50. The spacer layer 33 is made of, for example, undoped InP, specifically, undoped or unintentionally doped InP.

Furthermore, the active layer 41 and the active layer 42 have different numbers of MQW layers. For example, the active layer 41 includes two layers of MQWs, and the active layer 42 includes four layers of MQWs.

With such a configuration, the light intensity distribution becomes as shown in FIG. 6. That is, in the stacked structure of the active layer 41, the waveguide layer 50, the spacer layer 33, and the active layer 42, the peak of light intensity is located below the central plane S1, that is, on the side closer to the spacer layer 31, The light intensity is greater on the lower side of the central plane S1 than on the upper side. The light intensity in the active layer 41 is greater than that in the active layer 42.

When the light intensity is varied in magnitude in this way, on the lower side of the central plane S1, the light is greatly amplified near the input end, and the amplification factor is saturated near the output end. On the other hand, above the central plane S1, the amplification factor is small near the input end, but the amplification factor increases near the output end, making a large contribution to the output of the SOA 1. Thereby, light can be efficiently amplified above and below the central plane S1, and the optical output can be improved.

The data of E shown in FIGS. 4 and 5 are simulation results of this embodiment. In the data of E, the active layers 41 and 42 are configured to include two layers and four layers of MQW, respectively, and the film thickness of the waveguide layer 50 is 0.6 um. As shown in FIGS. 4 and 5, in this embodiment as well, the gain (amplification factor) in the large output region and the saturation output power are larger than those of the SOA 101, 102.

In the present embodiment, it is possible to achieve the advantageous effects as similar to the effects in the first embodiment with the configuration and operation identical to the first embodiment.

According to the second embodiment, it is possible to attain the following advantageous effects.
(1) The stacked structure of the active layers 41 and 42 and the waveguide layer 50 is asymmetrical with respect to the central plane S1. According to this, the optical output of the entire SOA 1 can be improved by adjusting the gain and the optical confinement coefficient, securing the gain near the input end of the SOA 1, and improving the saturation output power near the output end of the SOA 1.

### Third Embodiment

A third embodiment will be described. This embodiment differs from the first embodiment in that the configurations of the active layer 40 and the waveguide layer 50, and other aspects are the same as in the first embodiment, so only the differences from the first embodiment are explained.

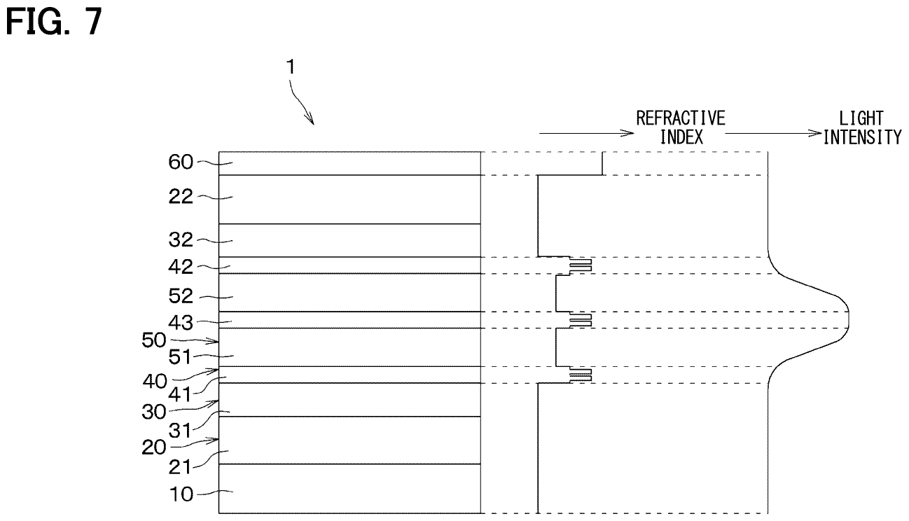

The waveguide layer 50 of this embodiment is composed of plural layers. Specifically, as shown in FIG. 7, the waveguide layer 50 includes a waveguide layer 51 disposed on the upper surface of the active layer 41 and a waveguide layer 52 disposed above the upper surface of the waveguide layer 51. Further, the active layer 40 includes an active layer 43 in addition to the active layers 41 and 42, and the active layer 43 is disposed between the waveguide layer 51 and the waveguide layer 52. That is, the active layer 40 and the waveguide layer 50 have a structure in which the active layer 41, the waveguide layer 51, the active layer 43, the waveguide layer 52, and the active layer 42 are stacked in this order on the upper surface of the spacer layer 31. The waveguide layers 51 and 52 correspond to a first waveguide layer and a second waveguide layer, respectively.

The waveguide layer 51, 52 is made of, for example, undoped InGaAsP, specifically, undoped or unintentionally doped InGaAsP. The active layer 41, 42, 43 includes, for example, two layers of MQW.

The waveguide layer 50 may be composed of three or more waveguide layers. In this case, among the plural waveguide layers constituting the waveguide layer 50, the waveguide layer located at the bottom corresponds to the first waveguide layer, and the waveguide layer located at the top corresponds to the second waveguide layer.

In this way, even in the configuration in which the waveguide layer 50 is divided by the active layer 40, the optical confinement coefficient can be reduced by adjusting the refractive index.

The data of F shown in FIGS. 4 and 5 are simulation results of this embodiment. In the data of F, the active layer 41, 42, 43 includes two layers of MQW, and the film thicknesses of the waveguide layer 51, 52 is 0.3 μm. As shown in FIGS. 4 and 5, in this embodiment as well, the gain (amplification factor) in the large output region and the saturation output power are larger than those of the SOA 101, 102.

In the present embodiment, it is possible to attain the advantageous effects as similar to the effects in the first embodiment with the configuration and operation identical to the first embodiment.

### Fourth Embodiment

A fourth embodiment will be described. Since the present embodiment is similar to the third embodiment except that the position of the active layer 43 is changed as compared with the third embodiment, only portions different from the third embodiment will be described.

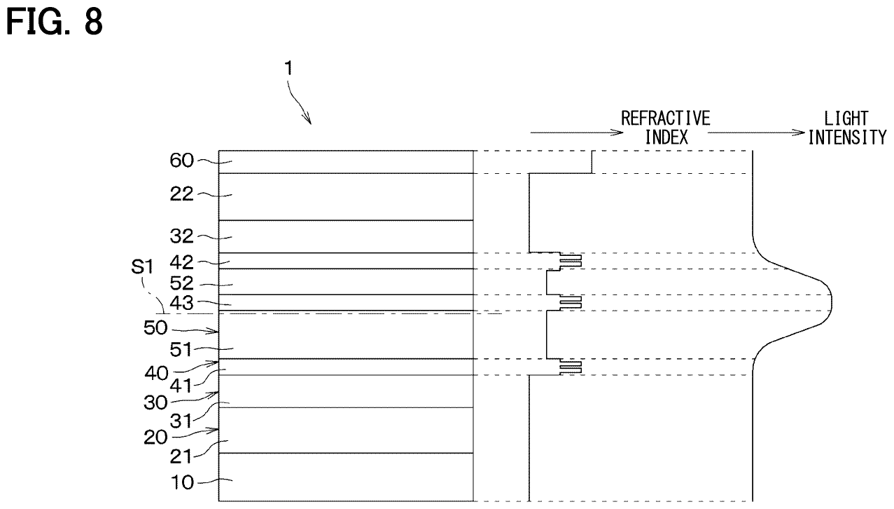

In the second embodiment, the stacked structure of the active layer 40 and the waveguide layer 50 is configured to be asymmetric depending on the number of active layers 41 and 42 and the distance from the active layers 41 and 42 to the central plane of the waveguide layer 50. In the third embodiment, by shifting the position of the active layer 43 from the central plane S1 in the thickness direction, the stacked structure of the active layer 40 and the waveguide layer 50 can be configured to be asymmetrical with respect to the central plane S1. For example, as shown in FIG. 8, the active layer 43 may be arranged above the central plane S1.

The data of G shown in FIGS. 4 and 5 are the simulation results of this embodiment. In the data of G, the active layer 41, 42, 43 includes two layers of MQW, and the film thicknesses of the waveguide layers 51, 52 are respectively 0.4 μm and 0.2 μm. As shown in FIGS. 4 and 5, in this embodiment as well, the gain (amplification factor) in the large output region and the saturation output power are larger than those of the SOA 101, 102.

This embodiment can obtain the same effects as the first to third embodiments from the same configuration and operation as the first to third embodiments.

### Fifth Embodiment

A fifth embodiment will be described. Since the present embodiment is similar to the first embodiment except the configuration of the active layer 40, as compared with the first embodiment, only portions different from the first embodiment will be described.

In the second embodiment, the stacked structure of the active layer 40 and the waveguide layer 50 is configured to be asymmetric depending on the number of active layers 41 and 42 and the distance from the active layers 41 and 42 to the central plane of the waveguide layer 50. Alternatively, by making the active layers 41 and 42 have different structures, the stacked structure of the active layer 40 and the waveguide layer 50 may be configured asymmetric with respect to the central plane S1. For example, the active layer 41 may include three layers of MQDs, and the active layer 42 may include three layers of MQWs.

Comparing SQWs and MQWs with SQDs and MQDs, if the number of layers is the same, SQWs and MQWs have larger gains than SQDs and MQDs. The saturation output power becomes larger since the optical confinement coefficients of SQDs and MQDs are smaller than those of SQWs and MQWs. Therefore, by adopting the configuration in which MQWs and MQDs are combined as described above, gain can be secured by MQWs near the input end of the SOA 1, and saturation output power can be improved by MQDs near the output end. Thereby, the output of the SOA 1 can be improved.

In the present embodiment, it is possible to attain the advantageous effects as similar to the effects in the first embodiment or the second embodiment with the configuration and operation identical to the first embodiment or the second embodiment.

### Other Embodiment

The present disclosure is not limited to the above-described embodiments, and can be appropriately modified. Individual elements or features of a particular embodiment are generally not limited to that particular embodiment, but, where applicable, are interchangeable and can be used in a selected embodiment, even if not specifically shown or described. Further, in each of the above-mentioned embodiments, it goes without saying that components of the embodiment are not necessarily essential except for a case in which the components are particularly clearly specified as essential components, a case in which the components are clearly considered in principle as essential components, and the like. Further, in each of the embodiments described above, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. The shape, the positional relationship, and the like of a component or the like mentioned in the above embodiments are not limited to those being mentioned unless otherwise specified, limited to specific shape, positional relationship, and the like in principle, or the like.

In the second to fourth embodiments, the structures of the active layers 41 and 42 may be different from each other as in the fifth embodiment. In the second embodiment, the stacked structure may be configured asymmetric with respect to the central plane S1 by changing only one of the number of layers of the active layer 41, 42 and the distance of the active layer 41, 42 to the central plane of the waveguide layer 50.

In order to distribute light in the center of the waveguide layer 50, the refractive index of the waveguide layer 50 may be changed depending on the position in the thickness direction. The refractive index of the waveguide layer 50 can be adjusted by the composition and ratio of the materials of the waveguide layer 50. For example, the refractive index of the central portion in the thickness direction may be higher than that of the upper surface layer portion and the lower surface layer portion of the waveguide layer 50. The refractive index of the waveguide layer 50 may be changed discontinuously, that is, in a stepwise manner, or may be changed continuously.

What is claimed is:

1. A semiconductor optical amplifier comprising:
a waveguide layer through which a light propagates; and
a plurality of active layers having a higher average refractive index than the waveguide layer, to amplify a light, wherein
the plurality of active layers has at least a first active layer stacked on an upper surface of the waveguide layer and a second active layer stacked on a lower surface of the waveguide layer.

2. The semiconductor optical amplifier according to claim 1, wherein
a stacked structure of the waveguide layer and the plurality of active layers is asymmetrical with respect to a central plane of the stacked structure in a thickness direction.

3. The semiconductor optical amplifier according to claim 2, wherein
the first active layer has a first distance to a central plane of the waveguide layer in the thickness direction, and the first distance is different from a second distance of the second active layer to the central plane of the waveguide layer in the thickness direction.

4. The semiconductor optical amplifier according to claim 2, wherein a number of layers is different between the first active layer stacked on the upper surface of the waveguide layer and the second active layer stacked on the lower surface of the waveguide layer.

5. The semiconductor optical amplifier according to claim 2, wherein a structure is different between the first active layer stacked on the upper surface of the waveguide layer and the second active layer stacked on the lower surface of the waveguide layer.

6. The semiconductor optical amplifier according to claim 5, wherein the active layers include at least one of a bulk structure, a single quantum well structure, a multiple quantum well structure, a single quantum dot structure, and a multiple quantum dot structure.

7. The semiconductor optical amplifier according to claim 1, wherein
the waveguide layer is one of a plurality of waveguide layers,
the plurality of waveguide layers includes a first waveguide layer located at a lowest position of the plurality of waveguide layers, and a second waveguide layer located at a highest position of the plurality of waveguide layers, and
the plurality of active layer has a first active layer stacked on a lower surface of the first waveguide layer, a second active layer stacked on an upper surface of the second waveguide layer, and a third active layer stacked between the first waveguide layer and the second waveguide layer.

8. The semiconductor optical amplifier according to claim 1, wherein the waveguide layer has a refractive index that changes depending on a position in a thickness direction.

9. The semiconductor optical amplifier according to claim 8, wherein the waveguide layer has a refractive index that changes stepwise.

10. The semiconductor optical amplifier according to claim 8, wherein
the waveguide layer has an upper surface layer portion, a central portion, and a lower surface layer portion in the thickness direction, and
the refractive index of the waveguide layer is higher in the central portion than in the upper surface layer portion and the lower surface layer portion.

11. The semiconductor optical amplifier according to claim 8, wherein the waveguide layer has a refractive index that changes continuously.
